(19) United States
(12) Patent Application Publication
(10) Pub. No.: US 2024/0313448 A1
(43) Pub. Date: Sep. 19, 2024

(54) Electrical Contact with Textured Contact Interface

(71) Applicant: TE Connectivity Solutions GmbH, Schaffhausen (CH)

(72) Inventors: Charles Raymond GINGRICH, III, Mechanicsburg, PA (US); Brian Todd KLINGER, Harrisburg, PA (US); Ranjan Deepak DESHMUKH, Mechanicsburg, PA (US); Suvrat BHARGAVA, Baltimore, MD (US)

(73) Assignee: TE Connectivity Solutions GmbH, Schaffhausen (CH)

(21) Appl. No.: 18/589,488

(22) Filed: Feb. 28, 2024

Related U.S. Application Data
(60) Provisional application No. 63/490,014, filed on Mar. 14, 2023.

(51) Int. Cl. H01R 12/72; H01R 13/193; H01R 13/26

(52) U.S. Cl. CPC H01R 12/721; H01R 13/193; H01R 13/26

(57) ABSTRACT

An electrical contact having at least one textured contact interface. The at least one textured contact interface includes a radiused portion with a plurality of raised contact areas. Voids are positioned between the plurality of raised contact areas. The radiused portion of the at least one textured contact interface provides more than one point of contact when the radiused portion of the at least one textured contact interface is positioned in electrical engagement with a mating electrical contact.

### CROSS REFERENCE TO RELATED APPLICATIONS

This application claims priority to U.S. Provisional Patent Application Ser. No. 63/490,014 filed on Mar. 14, 2023 which is incorporated herein by reference in its entirety.

### FIELD OF THE INVENTION

The invention relates to an electrical contact with a textured contact interface to improve connector reliability under harsh environment conditions. In particular, the textured contact interface provides more than one point of possible contact over wider ranges of tolerance and alignment.

### BACKGROUND OF THE INVENTION

Electrical connectors are plugged together with a mating connector in order to produce an electrical connection. Electrical connectors are generally used either for signal transmission or for power transmission and can be defined as an electromechanical system which provides a separable interface between two electronic subsystems. For this purpose, electrical connectors normally have electrically conductive contacts or terminals that engage conductive contacts or terminals of the mating connector when plugged together to make an electrical and mechanical connection therebetween. In many applications, when the connector and mating connector are plugged-together, one or both of the conductive contacts of the connector and the conductive contacts of the mating connector exert forces on the other in order to guarantee a reliable, electrically conductive connection.

In many applications the connectors and contacts are exposed to harsh environmental conditions, such as moisture, temperature variations, vibrations, and corrosive media. Exposure to such environments can result in the formation of insulating oxide layers in contact areas and therefore to the malfunction of connectors.

It would therefore be beneficial to provide contacts with textured contact surfaces which improves the reliability of the electrical connection between the contacts and the mating contacts improves contact reliability in general, but also under harsh environment conditions. In particular, it would be beneficial to provide textured contact surfaces which provide two or more contact points to improve contact reliability under high vibration conditions and which can change with changing tolerance/alignment of the contacts.

### SUMMARY OF THE INVENTION

The following provides a summary of certain illustrative embodiments of the present invention. This summary is not an extensive overview and is not intended to identify key or critical aspects or elements of the present invention or to delineate its scope.

The connector system includes textured contact interfaces to improve connector reliability under harsh environment conditions. The textured beam can provide two or more points of contact over a wide range of connector tolerance stack up. The textured contact face can provide a reservoir of contact lubricant that can be drawn into the mating contact point over time/mating cycles.

The two points of contact improves connector reliability under high vibration conditions. This method of attaining two points of contact works over a greater range of connector tolerance stack up than previous designs. Also, the lubricant reservoir can provide better reliability over more mating cycles.

The texture can be accomplished by various manufacturing methods and may have different geometry. For example, the textured pattern may be stamped into the contact face using progressive die tooling. In an embodiment, the texture could be applied by laser or other methods.

An embodiment is directed to an electrical contact having at least one textured contact interface. The at least one textured contact interface has a plurality of raised contact areas with voids positioned between the plurality of raised contact areas. The at least one textured contact interface provides more than one point of contact when the at least one textured contact interface is positioned in electrical engagement with a mating electrical contact.

An embodiment is directed to an electrical contact having at least one textured contact interface. The at least one textured contact interface includes a radiused portion with a plurality of raised contact areas. Voids are positioned between the plurality of raised contact areas. The radiused portion of the at least one textured contact interface provides more than one point of contact when the radiused portion of the at least one textured contact interface is positioned in electrical engagement with a mating electrical contact.

An embodiment is directed to an electrical contact having at least one textured contact interface. The at least one textured contact interface having a plurality of raised contact areas with voids positioned between the plurality of raised contact areas. Lubricant is provided in the voids. The raised contact areas of the at least one textured contact interface provides more than one point of contact when the raised contact areas of the at least one textured contact interface are positioned in electrical engagement with a mating electrical contact.

Additional features and aspects of the present invention will become apparent to those of ordinary skill in the art upon reading and understanding the following detailed description of the exemplary embodiments. As will be appreciated by the skilled artisan, further embodiments of the invention are possible without departing from the scope and spirit of the invention. Accordingly, the drawings and associated descriptions are to be regarded as illustrative and not restrictive in nature.

### BRIEF DESCRIPTION OF THE DRAWINGS

FIG. 1 is a perspective view of a first illustrative embodiment of an electrical contact according the present invention, the contact has a single beam configuration with a textured contact interface in the contact area.

FIG. 2 is a perspective view of a second illustrative embodiment of an electrical contact according the present invention, the contact has a bifurcated beam configuration with textured contact interfaces in the contact areas.

FIG. 3 is a perspective view of a third illustrative embodiment of an electrical contact according the present invention, the contact has a bifurcated inchworm beam configuration with textured contact interfaces in the contact areas.

FIG. 4 is a diagrammatic representation of the textured contact area of a beam of the contact in electrical engagement with a mating contact or mating area of a wafter, the textured contact area of a beam of the contact is shown in a first orientation relative to the mating area of the wafer.

FIG. 5 is a diagrammatic representation of the textured contact area of a beam of the contact in electrical engagement with a mating contact or mating area of a wafter, the textured contact area of a beam of the contact is shown in a second orientation relative to the mating area of the wafer.

FIG. 6 is a diagrammatic representation of the textured contact area of a beam of the contact in electrical engagement with a mating contact or mating area of a wafter, the textured contact area of a beam of the contact is shown in a third orientation relative to the mating area of the wafer.

FIG. 7 is an enlarged view of the textured contact area of a beam of the contact illustrating the texturing is applied at an angle relative to a longitudinal axis of the contact, the texturing is applied across the face of the contact area of a beam of the contact so when contact is made to the flat mating area of the wafer, there are at least two points of contact between the textured contact area of a beam of the contact and the mating area of the wafer.

FIG. 8 is an enlarged view of the textured contact area of a beam of the contact showing contact lubricant provided in the voids between the raised areas.

FIG. 9 is diagrammatic representation illustrating the textured contact areas of the beams of the contacts mated with the mating area of the wafer.

FIG. 9A is an enlarged portion of the area labeled 9A in FIG. 9, illustrating the line of contact between the textured contact areas of the beams of the contacts mated and the mating area of the wafer, the line of contact between the textured contact areas of the beams of the contacts mated and the mating area of the wafer is provided across two raised areas of the textured contact areas to provide two points of contact which vary according to the tolerance and alignment of the textured contact areas of the beams of the contacts mated and the mating area of the wafer.

FIG. 9B is an enlarged portion of the area labeled 9B in FIG. 9, illustrating the line of contact between the textured contact areas of the beams of the contacts mated and the mating area of the wafer, the line of contact between the textured contact areas of the beams of the contacts mated and the mating area of the wafer is provided across two raised areas of the textured contact areas to provide two points of contact which vary according to the tolerance and alignment of the textured contact areas of the beams of the contacts mated and the mating area of the wafer.

FIG. 10 is a section of a textured contact area illustrating a first alternate illustrative configuration of the raised contact areas and voids.

FIG. 11 is a section of a textured contact area illustrating a second alternate illustrative configuration of the raised contact areas and voids.

The accompanying drawings, which are incorporated into and form a part of the specification, schematically illustrate one or more exemplary embodiments of the invention and, together with the general description given above and detailed description given below, serve to explain the principles of the invention.

### DETAILED DESCRIPTION OF THE INVENTION

The description of illustrative embodiments according to principles of the present invention is intended to be read in connection with the accompanying drawings, which are to be considered part of the entire written description. In the description of embodiments of the invention disclosed herein, any reference to direction or orientation is merely intended for convenience of description and is not intended in any way to limit the scope of the present invention. Relative terms such as “lower,” “upper,” “horizontal,” “vertical,” “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation unless explicitly indicated as such. Terms such as “attached,” “affixed,” “connected,” “coupled,” “interconnected,” and similar refer to a relationship wherein structures are secured or attached to one another either directly or indirectly through intervening structures, as well as both movable or rigid attachments or relationships, unless expressly described otherwise. Moreover, the features and benefits of the invention are illustrated by reference to the preferred embodiments. Accordingly, the invention expressly should not be limited to such preferred embodiments illustrating some possible non-limiting combination of features that may exist alone or in other combinations of features, the scope of the invention being defined by the claims appended hereto.

Exemplary embodiments of the present invention are now described with reference to the Figures. Reference numerals are used throughout the detailed description to refer to the various elements and structures. Although the following detailed description contains many specifics for the purposes of illustration, a person of ordinary skill in the art will appreciate that many variations and alterations to the following details are within the scope of the invention. Accordingly, the following embodiments of the invention are set forth without any loss of generality to, and without imposing limitations upon, the claimed invention.

Referring to FIG. 1, an illustrative embodiment of an electrical contact 10 is shown. The contact 10 has circuit board mounting section 12, a housing securing section 14 and a mating section 16. In the embodiment shown, the circuit board mating section 12 has an eye of the needle configuration, but other configurations may be used. The circuit board mating section 12 is configured to make a mechanical and electrical connection with a circuit board (not shown). Alternative type of mounting sections 12 may be used.

In the embodiment shown, the securing section 14 has a barbs 18 and a lance 20. The barbs 18 and lance 20 are configured to cooperate with a housing (not shown) of an electrical connector (not shown) to retain the contact 10 is position relative to the housing of the electrical connector. Alternative configurations of the securing section 14 may be used.

In the embodiment shown, the mating section 16 extends from the securing section 14 in a direction away from the mounting section 12. The mating section 16 has a single contact arm 30 extending from a free end 32 of the mating section 16. Other configuration of the contact arm 30 may be used.

Each contact arm 30 has a radiused contact portion 34 provided between the free end 32 of the mating section 16 and the securing section 14. The mating section 16 extends from the securing section 14 at an angle, wherein the radiused contact portion 34 of each contact arm is offset from the plane of the securing section 14.

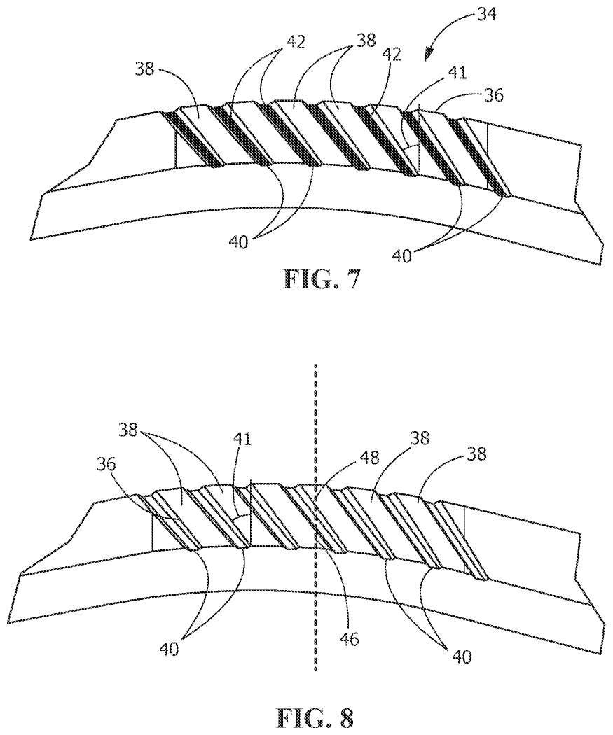

Each radiused contact portion 34 has a textured contact interface 36. As shown in FIG. 7, the textured contact interface 36 has a plurality of raised contact areas 38. The raised contact areas 38 are separated by voids or valleys 40.

The raised contact areas 38 and voids 40 are applied at an angle 41 across the face of the textured contact interface 36 of the radiused contact portion 34. In various illustrative embodiments the raised contact areas 38 extend at an angle 41 between 0 degrees and 90 degrees relative to a line perpendicular to the longitudinal axis of the contact arm 30 of the mating section 16 of the electrical contact 10. In various other illustrative embodiments the raised contact areas 38 extend at an angle 41 of between 20 degrees and 70 degrees relative to a longitudinal axis of the contact arm 30 of the mating section 16 of the electrical contact 10. The voids 40 extend at the same angle 41 relative to a longitudinal axis of the electrical contact 10 as the raised contact areas 38.

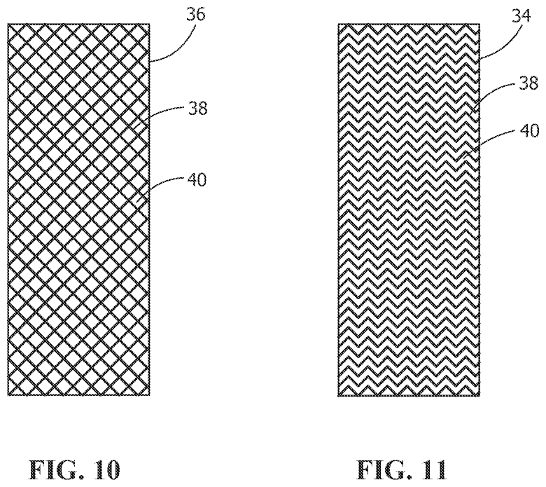

The configuration of the textured contact interface 36 shown in FIGS. 1-8 is meant to be illustrative. The raised contact areas 38 and voids 40 of the textured contact interface 36 can take on many configurations, such as, but not limited to, the configurations shown in FIGS. 10 and 11. The raised contact areas 38 and voids 40 may be manufactured by laser or other known methods.

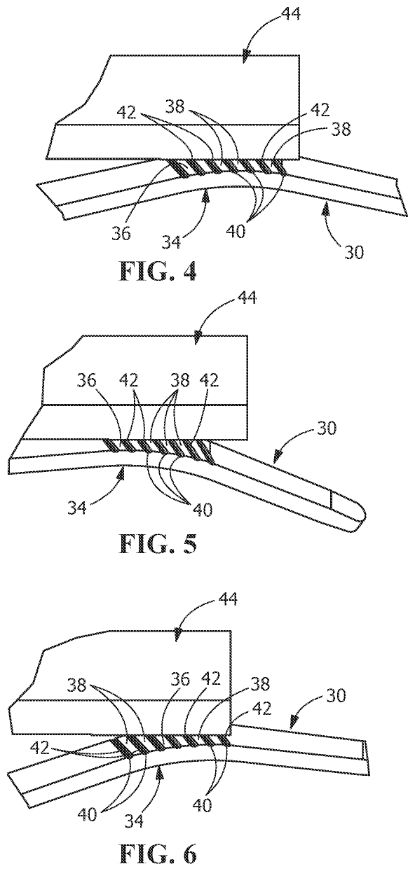

As shown in FIG. 7, lubricant 42 may be provided in the voids 40. During mating of the contact 10 to a mating contact or mating substrate 44 (FIGS. 4 through 6), the lubricant can migrate from the voids 40 to the raised contact areas 38. The lubricant may be any lubricant that provides lubricating properties to protect the surface to which it is applied and allows for multiple mating cycles. The lubricant may be, but is not limited to, a solid lubricant, such as graphite, or a liquid lubricant.

As the contact interfaces 36 of the contact 10 are mated with the mating contact or mating substrate 44, the lubricant 42 is transferred, deposited or applied to the raised contact areas 38 by a wiping action or the like. Continued mating causes the mating contact or mating substrate 44 to move into engagement with the voids 40 and lubricant 42. As this occurs, the lubricant 42 from the voids 40 is transferred, deposited or applied to the raised contact areas 38 by a wiping action or the like.

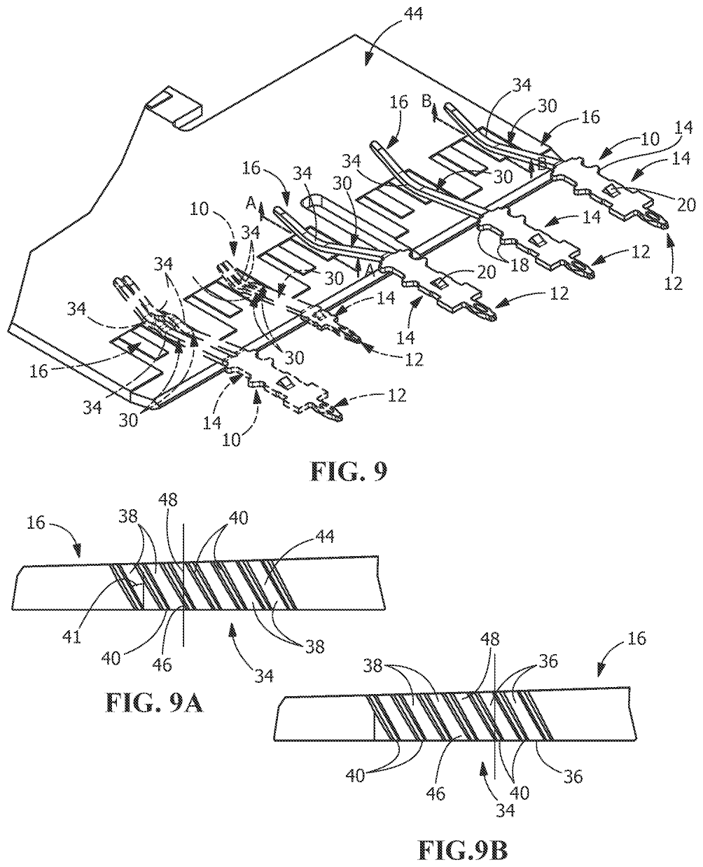

The textured contact interface 36 improves contact 10 reliability under harsh environment conditions, as angled raised contact areas 38 provide two or more points of contact 46, 48 (FIG. 7) over a wide range of connector tolerance stack up. The two or more points of contact improves contact reliability under high vibration conditions. The points of contact 46, 48 can change with tolerance/alignment, as represented in FIGS. 4-6 and FIGS. 9A and 9B.

The textured contact face can provide a reservoir of contact lubricant that can be drawn into the mating contact point over time/mating cycles. Also, the lubricant reservoir can provide better reliability over more mating cycles.

The raised contact areas 38 and voids 40 of the textured contact interface 36 can be accomplished by various manufacturing methods and may have different geometry. For example, the textured contact interface 36 may be stamped into the contact face using progressive die tooling or the textured contact interface 36 may be applied by laser or other methods.

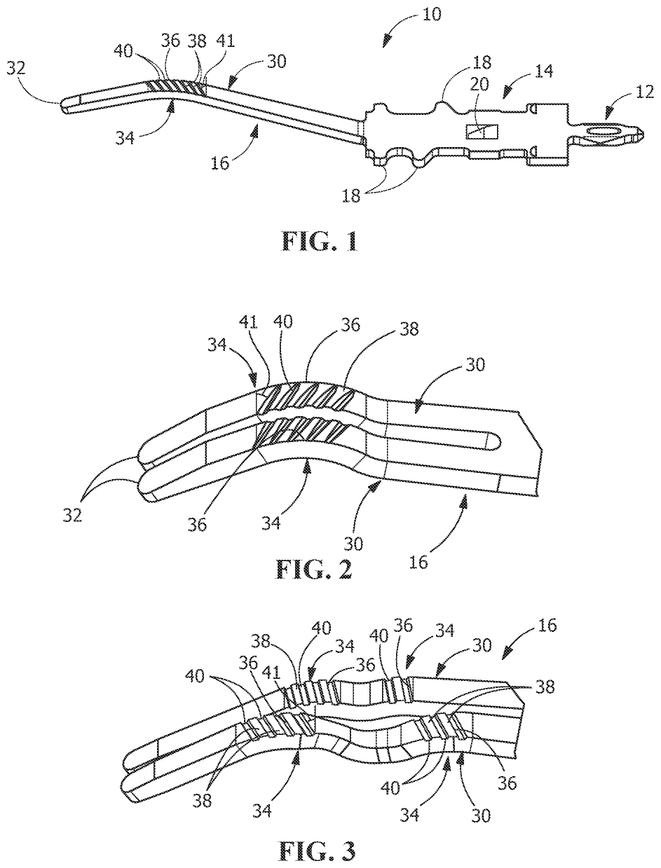

Referring to FIG. 2, an alternate embodiment of a contact 10 is shown. The mating section 16 has bifurcated contact arms 30 extending from a free end 32 of the mating section 16. In the embodiment shown, the bifurcated contact arms 30 have a similar configuration, however, the bifurcated contact arms 30 may have different configurations.

Each contact arm 30 has a radiused contact portion 34. Each radiused contact portion 34 has a textured contact interface 36. The textured contact interface 36 has a plurality of raised contact areas 38. The raised contact areas 38 are separated by voids or valleys 40. The raised contact areas 38 and voids 40 are applied at an angle 41 across the face of the textured contact interface 36 of the radiused contact portion 34.

The other features and operation of contact 10 shown in FIG. 2 is similar to that described above.

Referring to FIG. 3, another alternate embodiment of a contact 10 is shown. The mating section 16 has bifurcated inchworm beam contact arms 30 extending from a free end 32 of the mating section 16.

Each contact arm 30 has two radiused contact portions 34. Each radiused contact portion 34 has a textured contact interface 36. The textured contact interface 36 has a plurality of raised contact areas 38. The raised contact areas 38 are separated by voids or valleys 40. The raised contact areas 38 and voids 40 are applied at an angle 41 across the face of the textured contact interface 36 of the radiused contact portion 34.

The other features and operation of contact 10 shown in FIG. 3 is similar to that described above.

Textured contact surfaces can be applied to any type of contact tip design including a bifurcated tip, single tip or other known designs. The textured contact surfaces provide more than one point of contact over wider ranges of tolerance and alignment than known contacts.

While the invention has been described with reference to a preferred embodiment, it will be understood by those skilled in the art that various changes may be made and equivalents may be substituted for elements thereof without departing from the spirit and scope of the invention as defined in the accompanying claims. One skilled in the art will appreciate that the invention may be used with many modifications of structure, arrangement, proportions, sizes, materials and components and otherwise used in the practice of the invention, which are particularly adapted to specific environments and operative requirements without departing from the principles of the present invention. The presently disclosed embodiments are therefore to be considered in all respects as illustrative and not restrictive, the scope of the invention being defined by the appended claims, and not limited to the foregoing description or embodiments.

What is claimed:

1. An electrical contact comprising:
at least one textured contact interface, the at least one textured contact interface comprising:
a plurality of raised contact areas;
voids positioned between the plurality of raised contact areas;
wherein the at least one textured contact interface provides more than one point of contact when the at least one textured contact interface is positioned in electrical engagement with a mating electrical contact.

2. The electrical contact as recited in claim 1, wherein the at least one textured contact interface is positioned on at least one radiused portion of the electrical contact.

3. The electrical contact as recited in claim 1, wherein the electrical contact has a single contact beam, the at least one textured contact interface positioned on the single contact beam.

4. The electrical contact as recited in claim 1, wherein the electrical contact has multiple contact beams, at least one of the at least one textured contact interface positioned on each of the multiple contact beams.

5. The electrical contact as recited in claim 4, wherein each of the multiple contact beams has one textured contact interface of the at least one textured contact interface positioned on a radiused portion of each of the multiple contact beams.

6. The electrical contact as recited in claim 4, wherein each of the multiple contact beams has a plurality of textured contact interfaces of the at least one textured contact interface positioned on radiused portions of each of the multiple contact beams.

7. The electrical contact as recited in claim 1, wherein the raised contact areas extend at an angle of between 0 degrees and 90 degrees relative to a longitudinal axis of the electrical contact.

8. The electrical contact as recited in claim 7, wherein the voids extend at the same angle relative to a longitudinal axis of the electrical contact as the raised contact areas.

9. The electrical contact as recited in claim 1, wherein the raised contact areas extend at an angle of between 20 degrees and 70 degrees relative to the longitudinal axis of the electrical contact.

10. The electrical contact as recited in claim 9, wherein the voids extend at the same angle relative to a longitudinal axis of the electrical contact as the raised contact areas.

11. The electrical contact as recited in claim 1, wherein lubricant is provided in the voids, wherein the lubricant can migrate from the voids to the raised contact areas when the at least one textured contact interface is positioned in electrical engagement with the mating electrical contact.

12. An electrical contact comprising:
at least one textured contact interface, the at least one textured contact interface comprising:
a radiused portion with a plurality of raised contact areas;
voids positioned between the plurality of raised contact areas;
wherein the radiused portion of the at least one textured contact interface provides more than one point of contact when the radiused portion of the at least one textured contact interface is positioned in electrical engagement with a mating electrical contact.

13. The electrical contact as recited in claim 12, wherein the electrical contact has a single contact beam, the radiused portion of at least one textured contact interface positioned on the single contact beam.

14. The electrical contact as recited in claim 12, wherein the electrical contact has multiple contact beams, at least one of the radiused portions of the at least one textured contact interface positioned on each of the multiple contact beams.

15. The electrical contact as recited in claim 12 wherein the raised contact areas extend at an angle of between 0 degrees and 90 degrees relative to a longitudinal axis of the electrical contact.

16. The electrical contact as recited in claim 15, wherein the voids extend at the same angle relative to a longitudinal axis of the electrical contact as the raised contact areas.

17. The electrical contact as recited in claim 12, wherein the raised contact areas extend at an angle of between 20 degrees and 70 degrees relative to the longitudinal axis of the electrical contact.

18. The electrical contact as recited in claim 17, wherein the voids extend at the same angle relative to a longitudinal axis of the electrical contact as the raised contact areas.

19. The electrical contact as recited in claim 12, wherein lubricant is provided in the voids, wherein the lubricant can migrate from the voids to the raised contact areas when the at least one textured contact interface is positioned in electrical engagement with the mating electrical contact.

20. An electrical contact comprising:
at least one textured contact interface, the at least one textured contact interface comprising:
a plurality of raised contact areas;
voids positioned between the plurality of raised contact areas;
lubricant provided in the voids;
wherein the raised contact areas of the at least one textured contact interface provides more than one point of contact when the raised contact areas of the at least one textured contact interface are positioned in electrical engagement with a mating electrical contact.
